(19) United States
(12) Patent Application Publication
(10) Pub. No.: US 2015/0255414 A1
(43) Pub. Date: Sep. 10, 2015

(54) SOLDER ALLOY TO ENHANCE RELIABILITY OF SOLDER INTERCONNECTS WITH NIPDAU OR NIAU SURFACE FINISHES DURING HIGH TEMPERATURE EXPOSURE

(71) Applicants: Pilin Liu, Chandler, AZ (US); Yan Li, Chandler, AZ (US); Deepak Goyal, Phoenix, AZ (US)

(72) Inventors: Pilin Liu, Chandler, AZ (US); Yan Li, Chandler, AZ (US); Deepak Goyal, Phoenix, AZ (US)

(21) Appl. No.: 14/200,920

(22) Filed: Mar. 7, 2014

(51) Int. Cl. H01L 23/00; H01L 25/065; B23K 35/26; H01L 25/00

(52) U.S. Cl. CPC H01L 24/16; H01L 24/09; H01L 24/81; H01L 25/50; H01L 25/0657; B23K 35/262; H01L 2924/014; H01L 2224/13111; H01L 2224/8181; H01L 2924/01047; H01L 2924/01029; H01L 2924/01028; H01L 2924/14; H01L 2225/06513; H01L 2225/06517; H01L 2224/05147

(57) ABSTRACT

Embodiments of the present disclosure describe solder compounds for electrically coupling integrated circuit (IC) substrates as well as methods for using the solder compounds to couple IC subtrates. The solder compounds are formulated with lower Copper (Cu) percentages to prevent the formation of Cu rich intermettalic compounds (IMCs) which may undergo transitions at elevated temperatures resulting in void formation when NiPdAu or NiAu surface finishes are used on both sides of the solder interconnect. Additionally, nickel (Ni), may be included in the solder compounds to improve fatigue and/or creep properties. Other embodiments may be described and/or claimed.

### FIELD

Embodiments of the present disclosure generally relate to the field of integrated circuit package assemblies, and more particularly, to solder compounds for electrically coupling components to one another as well as package assemblies and methods for fabricating package assemblies employing the solder compounds.

### BACKGROUND

As package assemblies become more complicated and require the coupling of different contacts with various metallization schemes, known solder compounds may fail to provide sufficient electrical coupling or reliability. NiPdAu or NiAu surface finishes are preferred over Cu or Cu OSP due to their slower reaction rate with Pb-free solders and higher electromigration resistance. A particular reliability issue is solder/IMC separation due to void formation during exposure to elevated temperatures when NiPdAu or NiAu are used on both sides of the solder interconnects.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1A-C schematically illustrate cross-section side views of a solder joint between interconnects, in accordance with some embodiments.

FIGS. 2A-C schematically illustrate cross-section side views of a solder joint between interconnects, in accordance with some embodiments.

FIGS. 3A-B schematically illustrate the vacancy fluxes during intermetallic compound (IMC) transformations, in accordance with some embodiments.

FIG. 4 schematically illustrates a portion of a phase diagram for a nickel (Ni), Copper (Cu), Tin (Sn) alloy, in accordance with some embodiments.

FIG. 5 schematically illustrates a method of making a package assembly utilizing a solder compound, in accordance with some embodiments.

FIG. 6 schematically illustrates a computing device that includes a solder compound as described herein, in accordance with some embodiments.

FIG. 7 schematically illustrates a cross section side view of a package assembly includes a solder compound as described herein, in accordance with some embodiments.

### DETAILED DESCRIPTION

Embodiments of the present disclosure describe solder compounds for electrically coupling contacts, integrated circuit (IC) package assemblies utilizing the solder compounds, and methods of fabricating IC package assemblies utilizing the solder compounds. These embodiments include solder compounds having decreased copper (Cu) content to control intermetallic compound (IMC) formation and prevent separation due to void formation in solder interconnects with NiPdAu or NiAu on both sides. In some embodiments nickel (Ni) may be included in the solder compound to improve fatigue and/or creep properties.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “in embodiments,” or “in some embodiments,” which may each refer to one or more of the same or different embodiments. Furthermore, the terms “comprising,” “including,” “having,” and the like, as used with respect to embodiments of the present disclosure, are synonymous.

The term “coupled with” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group) and/or memory (shared, dedicated, or group) that execute one or more software or firmware programs, a combinational logic circuit, and/or other suitable components that provide the described functionality.

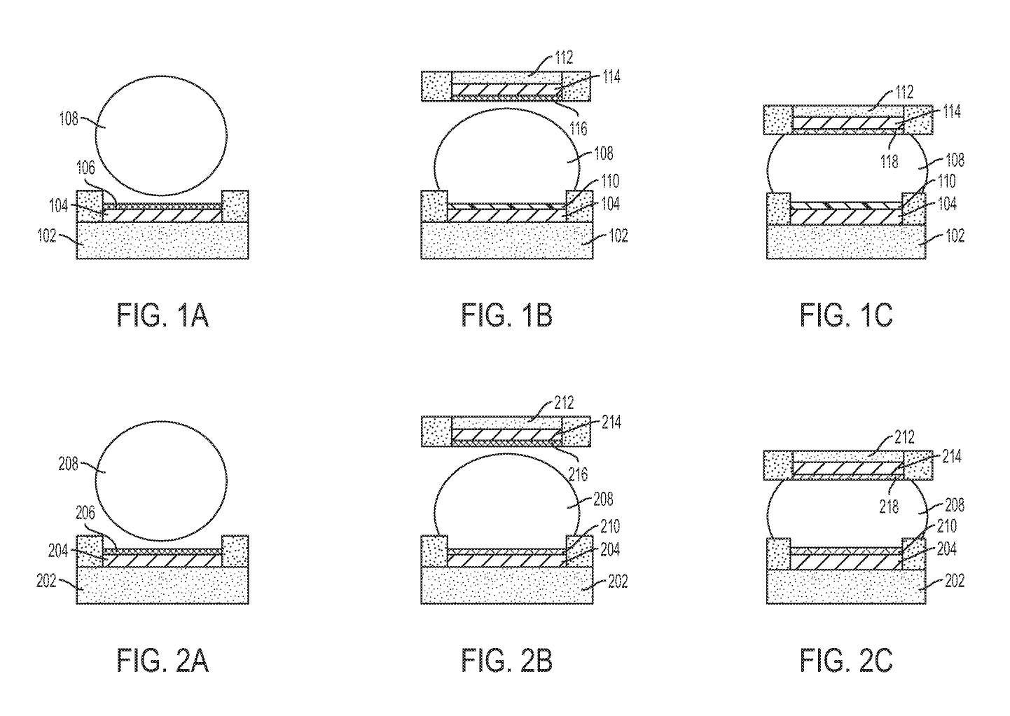

FIGS. 1A-C illustrate a solder joint formed between two contacts using traditional solder. The solder 108 may be a combination of tin (Sn), silver (Ag), and copper (Cu) having relative percentages by weight of 95.5% Sn, 4% Ag, and 0.5% Cu. Such solder is commonly referred to as SAC 405 where SAC refers to Sn, Ag, and Cu and 405 refers to the 4% Ag and 0.5% Cu with the remaining material made up of Sn. SAC 405 and SAC 305 (96.5% Sn, 3% Ag, 0.5% Cu) are lead (Pb) free solders commonly used in IC fabrication.

FIG. 1A shows a Cu pad 102 with a nickel (Ni) layer 104 disposed on the Cu pad 102. The Cu pad 102 may be associated with an IC substrate or a circuit board which is to be coupled to another IC substrate or circuit board. The Cu pad 102 may be one of a series of contacts associated with an IC substrate or circuit board. A layer 106 of a combination of palladium (Pd) and gold (Au) is disposed on the Ni layer 104. This arrangement of layers may be referred to as a NiPdAu contact or interconnect, referring to the Ni layer 104 and the Pd/Au layer 106.

As shown in FIG. 1B the solder 108 (such as SAC 405) is brought into contact with the Pd/Au layer 106. This results in a reaction that creates an intermetallic compound (IMC) layer 110 through which the Ni layer 104 is coupled, both electrically and mechanically, to the solder 108. When solder 108 is SAC 405 the IMC layer 110 that is formed will consist predominately of an alloy according to the ratio of (Cu,Ni)₆Sn₅. For the purposes of this disclosure the word predominately is used to refer to a constituent that makes up the greatest percentage of a given structure as compared to any other single constituent. (Cu,Ni)₆Sn₅ may be referred to as a Cu rich IMC because the Cu and Ni are more prevalent than Sn. During the reaction Cu from the solder 108 migrates to the IMC layer 110 leaving the solder 108 with a lower concentration of Cu after the formation of the IMC layer 110.

FIG. 1B also includes a Cu pad 112 associated with a different IC substrate or circuit board that is to be coupled with the IC substrate or circuit board associated with Cu pad 102. Similar to Cu pad 102, Cu pad 112 also includes a Ni layer 114 and a Pd/Au layer 116.

As shown in FIG. 1C upon being brought into contact with solder 108 another reaction occurs to form another IMC layer 118 coupling solder 108 to Ni layer 114. Unlike the Cu rich IMC layer 110, IMC layer 118 will consist predominately of an alloy according to the ratio of (Cu,Ni)₃Sn₄ when solder 108 is SAC 405. The difference in IMC constituents is due to the depleted Cu content of solder 108 during formation of IMC layer 118. As discussed in more detail below, the different alloys present in IMC layer 110 as compared to IMC layer 118 may cause reliability issues when the solder joint is exposed to elevated temperatures. In particular, due to the limited Cu available the (Cu,Ni)₆Sn₅ in IMC 110 may transform into (Cu,Ni)₃Sn₄ at elevated temperatures resulting in the formation of voids between solder 108 and IMC 110. Void formation may cause separation or insufficient coupling.

FIGS. 2A-C illustrate a solder joint formed between two contacts using solder according to the current disclosure. In general solder 208 includes less Cu than traditional solders (such as SAC 405) to prevent the formation of (Cu,Ni)₆Sn₅ during formation of the IMC layers. By preventing the formation of the (Cu,Ni)₆Sn₅ alloy the later transition to the (Cu,Ni)₃Sn₄ alloy at elevated temperature may be avoided thus preventing void formation and the deleterious effects associate therewith.

Solder 208 may contain from 0.01% to 0.375% by weight Cu. In some embodiments, solder 208 may contain from 0.1% to 0.3% by weight Cu. In some embodiments solder 208 may contain approximately 0.2% by weight Cu.

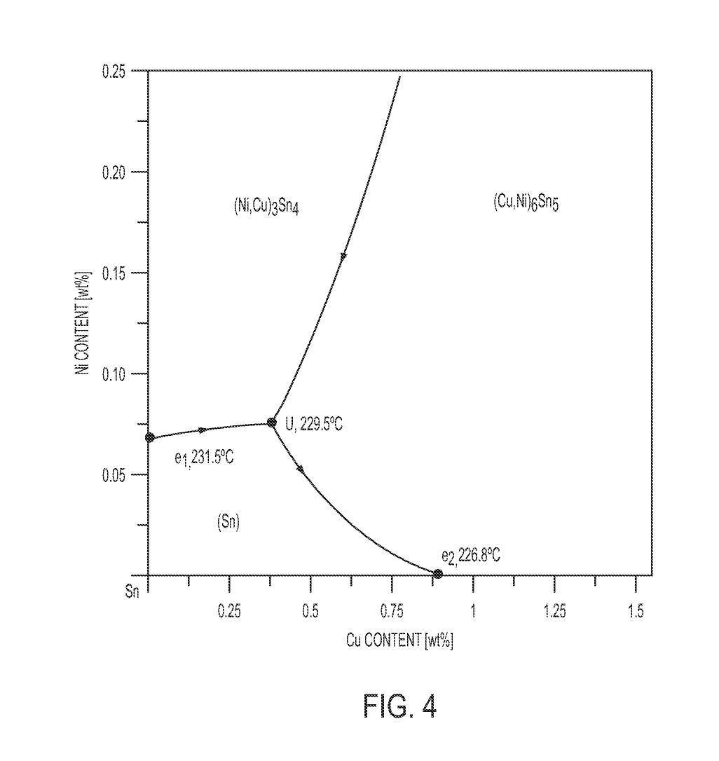

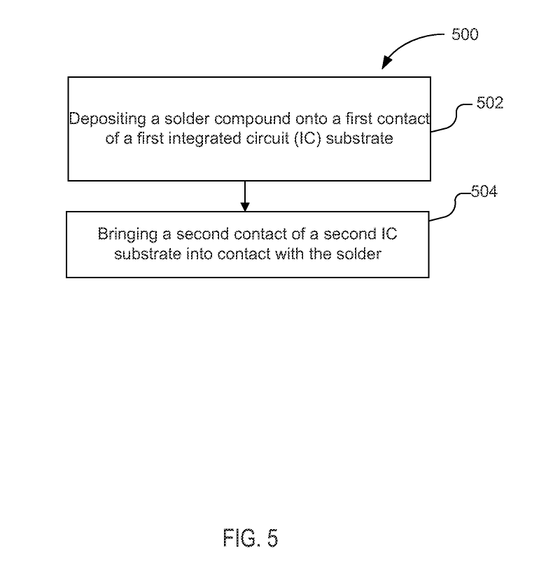

FIG. 4 shows a portion of a Cu—Ni—Sn phase diagram. As can be seen in the phase diagram, at concentrations below approximately 0.375% by weight Cu it is not possible to form the (Cu,Ni)₆Sn₅ alloy. Thus by reducing the amount of Cu in the solder it is possible to avoid the formation of the (Cu,Ni)₆Sn₅ alloy.

Solder 208 may also contain Ni. The Ni may enhance the fatigue and/or creep properties of the solder 208. Solder 208 may contain from 0.01% to 0.3% by weight Ni. In some embodiments solder 208 may contain approximately 0.1% by weight Ni.

Similar to FIG. 1 discussed above, FIG. 2A shows a Ni layer 204 formed on a Cu pad 202. The Cu pad 202 may be associated with an IC substrate or a circuit board, which is to be coupled to another IC substrate or circuit board. The Cu pad 202 may be one of a series of contacts associated with an IC substrate or circuit board. A Pd/Au layer 206 is disposed on the Ni layer 204.

FIG. 2B shows the solder 208 after it has been brought into contact with, and reacted with, the Pd/Au layer 206 to form an IMC layer 210. Unlike, IMC layer 110, discussed above relative to FIG. 1B, IMC layer 210 contains predominately the (Cu,Ni)₃Sn₄ alloy because the reduced Cu in solder 208 prevents the formation of the (Cu,Ni)₆Sn₅ alloy. FIG. 2B also includes a Cu pad 212 associated with a different IC substrate or circuit board that is to be coupled with the IC substrate or circuit board associated with Cu pad 202. Similar to Cu pad 202, Cu pad 212 also includes a Ni layer 214 and a Pd/Au layer 216. Cu pads 202 and 212 may associated with dies, substrates, circuit boards or other components such that solder 208 may be used form first level interconnects (FLI) or second level interconnects (SLI).

FIG. 2C shows the solder joint after the Pd/Au layer 216 has been brought into contact with the solder 208 and allowed to react to form IMC layer 218. Similar to IMC layer 210 (and 118 in FIG. 1C) IMC layer 218 is composed predominately of the (Cu,Ni)₃Sn₄ alloy.

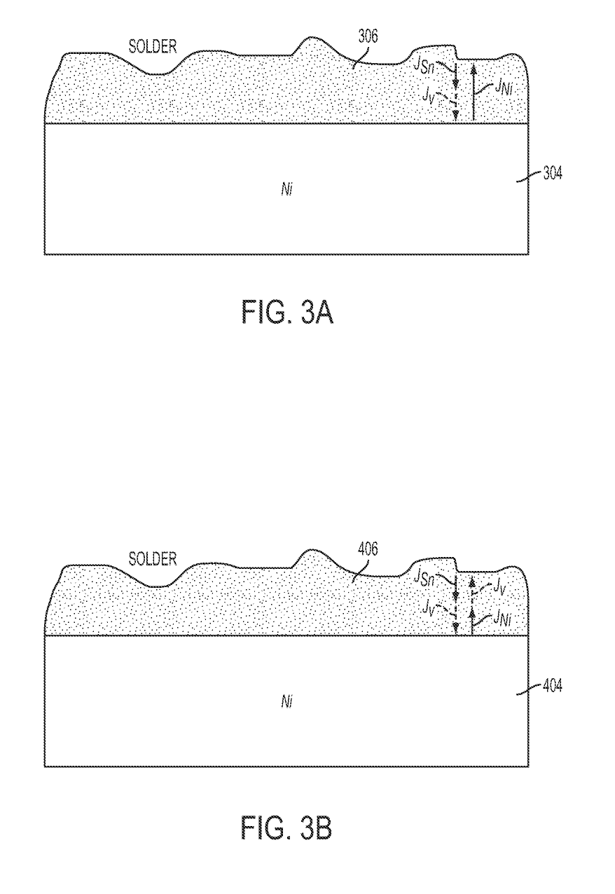

FIGS. 3A-B illustrate the diffusion of various materials, as well as the vacancy flux, around the IMC (i.e. IMC 110, 118, 210 218). FIG. 3A shows the formation of the initial IMC (i.e. IMC 110, 118, 210 218) whereas FIG. 3B shows the transition of the (Cu,Ni)₆Sn₅ alloy to the (Cu,Ni)₃Sn₄ alloy, as may occur at elevated temperatures.

As seen in FIG. 3A during initial IMC formation Ni diffuses from the Ni layer 304 into the IMC 306 towards the interface of the IMC 306 and the solder. This is shown as the arrow labeled J_{Ni}. Sn diffuses from the solder through the IMC 306 towards the interface of the IMC 306 and the Ni layer 304. This is shown by the arrow labeled J_{Sn}. The Ni diffusion through the IMC 306 is more dominant than the Sn diffusion towards the Ni layer 304 resulting in a vacancy flux towards the Ni layer 304 to balance the difference. This vacancy flux is shown as the arrow labeled J_{V}. Thus there is no vacancy source to form voids at the interface between the IMC 306 and solder because there is no vacancy flux towards this interface.

By contrast, in FIG. 3B it can be seen that there is an additional vacancy flux towards the interface between the IMC 406 and the solder when the IMC is undergoing a transition from the (Cu,Ni)₆Sn₅ alloy to the (Cu,Ni)₃Sn₄ alloy. This additional vacancy flux is shown by the upward directed arrow labeled J_{V}. During this transition both Sn and Ni will diffuse into the IMC 406. Ni diffuses from the Ni layer 404 into the IMC 406 as shown by the arrow labeled J_{Ni}. Sn diffuses from the solder into the IMC 406 as shown by the arrow labeled J_{Sn}. The presence of the additional vacancy flux towards the interface between the IMC 406 and solder may result in void formation.

The transformation shown in FIG. 3B may occur when both contacts being coupled by the solder joint utilize the NiPdAu metallization scheme. This may be due to the fact that there is a shortage of Cu during IMC formation. In instances where at least one of the two contacts being coupled has Cu readily available during IMC formation there may not be a Cu deficiency during IMC formation thus preventing the transition and the resulting void formation. Therefore the problem may only be observed when coupling contacts with particular metallization schemes, such as two contacts both having NiPdAu metallization.

As mentioned previously FIG. 4 shows a portion of a Cu—Ni—Sn phase diagram. Although traditional SAC 405 solder does not contain Ni, due to the Ni layer (e.g., 104, 204 etc.) Ni is present during the formation of the IMC layers (e.g., 110, 210). As can be seen from FIG. 4, with solder including 0.5% by weight Cu (such as SAC 305 or SAC 405) the (Cu,Ni)₆Sn₅ alloy may form during formation of the IMC layer if the correct amount of Ni is present. As discussed previously though, if the solder contains approximately 0.375% or less by weight Cu it may not be possible to from the (Cu,Ni)₆Sn₅ alloy. Thus limiting the Cu content of the solder may control the alloy that forms during IMC formation and thus may prevent future transitions from the (Cu,Ni)₆Sn₅ alloy to the (Cu,Ni)₃Sn₄ alloy, which can occur at elevated temperatures and which may generate voids for the reasons discussed above.

FIG. 5 shows a method 500 for coupling IC substrates in accordance with some embodiments. The method 500 starts at 502 with depositing a solder compound onto a first contact of a first IC substrate. The depositing may be achieved by any suitable technique and may include simultaneously depositing solder on a plurality of contacts of a single IC substrate or multiple IC substrates.

The method 500 continues at 504 with bringing a second contact of a second IC substrate into contact with the solder. This may be achieved by any suitable technique and may include simultaneously bringing a plurality of contacts of a single IC substrate or multiple IC substrates into contact with solder previously deposited on complimentary contacts of other IC substrates. In addition to coupling contacts of two IC substrates, the method 500, and the solder compounds discussed herein, may also be used to couple an IC substrate to a circuit board, or a circuit board to another circuit board. In general, the solder compounds discussed herein may be used in any application where lead free solder is used to couple electrical components.

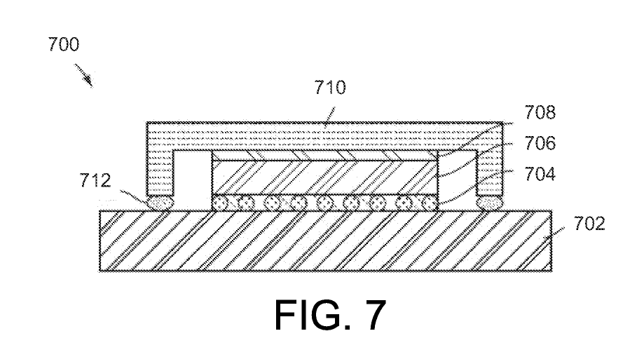

FIG. 7 illustrates a package assembly 700 utilizing a solder compound discussed herein. The package assembly 700 may include die 706 coupled to a substrate 702 by way of solder ball 704. Solder balls 704 may be made from solder compound discussed herein, alternatively, solder compounds discussed herein may be utilized to couple solder balls 704 to both the die 706 and the substrate 702. The package assembly 700 may also include an integrated heat spreader 710 thermally coupled to the die 706 via a thermal interface material 708. The integrated heat spreader 710 may also be mechanically coupled to the substrate 702. Substrate 702 may also be configured to be coupled to a circuit board (not shown) via a solder compound as discussed herein.

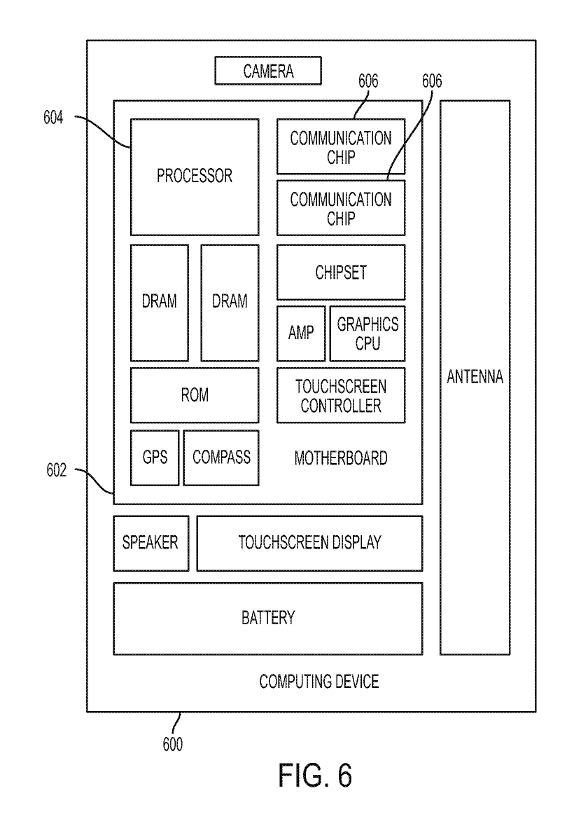

Embodiments of the present disclosure may be implemented into a system using any suitable hardware and/or software to configure as desired. FIG. 6 schematically illustrates a computing device 600 that includes an IC package assembly utilizing solder compounds as described herein, in accordance with some embodiments. The computing device 600 may include housing to house a board such as motherboard 602. Motherboard 602 may include a number of components, including but not limited to processor 604 and at least one communication chip 606. Processor 604 may be physically and electrically coupled to motherboard 602. In some implementations, the at least one communication chip 606 may also be physically and electrically coupled to motherboard 602. In further implementations, communication chip 606 may be part of processor 604.

Depending on its applications, computing device 600 may include other components that may or may not be physically and electrically coupled to motherboard 602. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

Communication chip 606 may enable wireless communications for the transfer of data to and from computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 606 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. Communication chip 606 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 806 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. Communication chip 806 may operate in accordance with other wireless protocols in other embodiments.

Computing device 600 may include a plurality of communication chips 606. For instance, a first communication chip 606 may be dedicated to shorter range wireless communications such as Wi-Fi and Bluetooth, and a second communication chip 606 may be dedicated to longer range wireless communications such as GPS, EDGE, GPRS, CDMA, WiMAX, LTE, Ev-DO, and others.

Processor 604 of computing device 600 may be packaged in an IC assembly utilizing the solder compounds described herein. For example, processor 604 may include a first level interconnect (FLI) between a die and a package substrate utilizing a solder compound as described herein. Furthermore, the package assembly and motherboard 602 may be coupled together using package-level interconnects utilizing a solder compound as described herein. The term “processor” may refer to any device or portion of a device that processes electronic data from registers and/or memory to transform that electronic data into other electronic data that may be stored in registers and/or memory.

Communication chip 606 may also include a die that may be packaged in an IC assembly utilizing the solder compounds described herein. The solder compounds may be used within the IC assembly or in the package-level interconnect coupling the communication chip 606 to the motherboard 602. In further implementations, another component (e.g., memory device or other integrated circuit device) housed within computing device 600 may include a die that may be packaged in an IC assembly utilizing the solder compounds described herein.

In various implementations, computing device 600 may be a laptop, a netbook, a notebook, an Ultrabook™, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Various operations are described as multiple discrete operations in turn, in a manner that is most helpful in understanding the claimed subject matter. However, the order of description should not be construed as to imply that these operations are necessarily order dependent.

### Examples

Some non-limiting examples are provided below.

Example 1 includes a solder compound comprising: from 1% to 5% by weight silver (Ag); from 0.01% to 0.375% by weight copper (Cu); and at least 90% by weight tin (Sn).

Example 2 includes the solder compound of example 1, wherein Ag makes up from 2.5% to 4.5% of the weight of the solder.

Example 3 includes the solder compound of example 2, wherein Ag makes up approximately 4% of the weight of the solder.

Example 4 includes the solder compound of example 1, wherein Cu makes up from 0.1% to 0.3% of the weight of the solder.

Example 5 includes the solder compound of any of examples 1-4, wherein Cu makes up approximately 0.2% of the weight of the solder.

Example 6 includes the solder compound of any of examples 1-4, further comprising: from 0.01% to 0.3% by weight nickel (Ni).

Example 7 includes the solder compound of claim 6, wherein Ni makes up approximately 0.1% of the weight of the solder.

Example 8 includes a package assembly comprising: a first integrated circuit (IC) substrate having a first contact; a second IC substrate having a second contact; and a solder joint between the first contact and the second contact, wherein the solder joint comprises: a first intermetallic compound (IMC) region adjacent to the first contact; and a second intermetallic compound (IMC) region adjacent to the second contact; wherein the first and second IMC regions are composed predominately of a combination of Nickel (Ni), Copper (Cu), and Tin (Sn) having the ratio (Ni,Cu)₃Sn₄.

Example 9 includes the package assembly of example 8, wherein each of the first contact and the second contact includes: a Cu pad; and a Ni layer disposed on the Cu pad.

Example 10 includes the package assembly of example 9 wherein the first and second IMC regions are in direct contact with the Ni layers of the respective first and second contacts.

Example 11 includes the package assembly of example 8, wherein the solder joint includes from 0.01% to 0.3% by weight Ni.

Example 12 includes the package assembly of any of examples 8-11, wherein Ni makes up approximately 0.1% of the weight of the solder joint.

Example 13 includes the package assembly of any of examples 8-11, wherein the solder joint includes from 0.1% to 0.3% by weight Cu.

Example 14 includes the package assembly of example 13, wherein Cu makes up approximately 0.2% of the weight of the solder joint.

Example 15 includes a method of making a package assembly, the method comprising: depositing a solder compound onto a first contact of a first integrated circuit (IC) substrate; and bringing a second contact of a second IC substrate into contact with the solder; wherein the solder includes: from 2.5% to 4.5% by weight silver (Ag); from 0.1% to 0.3% by weight copper (Cu); and at least 90% by weight tin (Sn).

Example 16 includes the method of example 15, wherein Ag makes up approximately 4% of the weight of the solder.

Example 17 includes the method of example 15, wherein Cu makes up approximately 0.2% of the weight of the solder.

Example 18 includes the method of any of examples 15-17, wherein the solder includes from 0.01% to 0.3% by weigh nickel (Ni).

Example 19 includes the method of claim 18, wherein Ni makes up approximately 0.1% of the weight of the solder.

Example 20 includes the method of any of examples 15-17, wherein, prior to contacting the solder, the first and second contacts both include: a Cu pad; a Ni layer formed on the Cu pad; and a layer including Palladium (Pd) and Gold (Au) formed on the Ni layer.

Example 21 includes a computing device comprising: a circuit board; and a package assembly coupled with the circuit board, the package assembly including: a die having a first contact; a package substrate having a second contact a solder joint between the first contact and the second contact, wherein the solder joint comprises: a first intermetallic compound (IMC) region adjacent to the first contact; and a second intermetallic compound (IMC) region adjacent to the second contact; wherein the first and second IMC regions are composed predominately of a combination of Nickel (Ni), Copper (Cu), and Tin (Sn) having the ratio (Ni,Cu)₃Sn₄.

Example 22 includes the computing device of example 21, wherein the package substrate has a third contact and the circuit board has a fourth contact, the computing device further comprising a second solder joint between the third contact and the fourth contact, where the second solder join comprises: a third intermetallic compound (IMC) region adjacent to the third contact; and a fourth intermetallic compound (IMC) region adjacent to the fourth contact; wherein the third and fourth IMC regions are composed predominately of a combination of Nickel (Ni), Copper (Cu), and Tin (Sn) having the ratio (Ni,Cu)₃Sn₄.

Example 23 includes the computing device of example 21, wherein the solder joint includes approximately 0.2% by weight Cu joint.

Example 24 includes the computing device of example 21, wherein the solder joint includes approximately 0.1% by the weight nickel (Ni).

Example 25 includes the computing device of any of examples 21-24, wherein: the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A solder compound comprising:
from 1% to 5% by weight silver (Ag);
up to 0.375% by weight copper (Cu); and
at least 90% by weight tin (Sn).

2. The solder compound of claim 1, wherein Ag makes up from 2.5% to 4.5% of the weight of the solder.

3. The solder compound of claim 2, wherein Ag makes up approximately 4% of the weight of the solder.

4. The solder compound of claim 1, wherein Cu makes up from 0.1% to 0.3% of the weight of the solder.

5. The solder compound of claim 1, wherein Cu makes up approximately 0.2% of the weight of the solder.

6. The solder compound of claim 1, further comprising:
up to 0.3% by weight nickel (Ni).

7. The solder compound of claim 6, wherein Ni makes up approximately 0.1% of the weight of the solder.

8. A package assembly comprising:
a first integrated circuit (IC) substrate having a first contact;
a second IC substrate having a second contact; and
a solder joint between the first contact and the second contact, wherein the solder joint comprises:
a first intermetallic compound (IMC) region adjacent to the first contact; and
a second intermetallic compound (IMC) region adjacent to the second contact;
wherein the first and second IMC regions are composed predominately of a combination of Nickel (Ni), Copper (Cu), and Tin (Sn) having the ratio (Ni,Cu)₃Sn₄.

9. The package assembly of claim 8, wherein each of the first contact and the second contact includes:
a Cu pad; and
a Ni layer disposed on the Cu pad.

10. The package assembly of claim 9 wherein the first and second IMC regions are in direct contact with the Ni layers of the respective first and second contacts.

11. The package assembly of claim 8, wherein the solder joint includes from 0.01% to 0.3% by weight Ni.

12. The package assembly of claim 8, wherein Ni makes up approximately 0.1% of the weight of the solder joint.

13. The package assembly of claim 8, wherein the solder joint includes from 0.1% to 0.3% by weight Cu.

14. The package assembly of claim 13, wherein Cu makes up approximately 0.2% of the weight of the solder joint.

15. A method of making a package assembly, the method comprising:
depositing a solder compound onto a first contact of a first integrated circuit (IC) substrate; and
bringing a second contact of a second IC substrate into contact with the solder;
wherein the solder includes:
from 2.5% to 4.5% by weight silver (Ag);
from 0.1% to 0.3% by weight copper (Cu); and
at least 90% by weight tin (Sn).

16. The method of claim 15, wherein Ag makes up approximately 4% of the weight of the solder.

17. The method of claim 15, wherein Cu makes up approximately 0.2% of the weight of the solder.

18. The method of claim 15, wherein the solder includes from 0.01% to 0.3% by weigh nickel (Ni).

19. The method of claim 18, wherein Ni makes up approximately 0.1% of the weight of the solder.

20. The method of claim 15, wherein, prior to contacting the solder, the first and second contacts both include:
a Cu pad;
a Ni layer formed on the Cu pad; and
a layer including Palladium (Pd) and Gold (Au) formed on the Ni layer.

21. A computing device comprising:
a circuit board; and
a package assembly coupled with the circuit board, the package assembly including:
a die having a first contact;
a package substrate having a second contact
a solder joint between the first contact and the second contact, wherein the solder joint comprises:
a first intermetallic compound (IMC) region adjacent to the first contact; and
a second intermetallic compound (IMC) region adjacent to the second contact;
wherein the first and second IMC regions are composed predominately of a combination of Nickel (Ni), Copper (Cu), and Tin (Sn) having the ratio (Ni,Cu)₃Sn₄.

22. The computing device of claim 21, wherein the package substrate has a third contact and the circuit board has a fourth contact, the computing device further comprising a second solder joint between the third contact and the fourth contact, where the second solder join comprises:
a third intermetallic compound (IMC) region adjacent to the third contact; and
a fourth intermetallic compound (IMC) region adjacent to the fourth contact;
wherein the third and fourth IMC regions are composed predominately of a combination of Nickel (Ni), Copper (Cu), and Tin (Sn) having the ratio (Ni,Cu)₃Sn₄.

23. The computing device of claim 21, wherein the solder joint includes approximately 0.2% by weight Cu joint.

24. The computing device of claim 21, wherein the solder joint includes approximately 0.1% by the weight nickel (Ni).

25. The computing device of claim 21, wherein:
the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.
